(19) United States
(12) Patent Application Publication
(10) Pub. No.: US 2026/0168740 A1
(43) Pub. Date: Jun. 18, 2026

(54) FLOW THRUSTER FOR HEAT PIPE MICROCHANNEL

(71) Applicant: Raytheon Company, Arlington, VA (US)

(72) Inventors: Edward Lawrence Hieb, Aubrey, TX (US); Travis Mayberry, Dallas, TX (US)

(21) Appl. No.: 19/389,615

(22) Filed: Nov. 14, 2025

Related U.S. Application Data
(60) Provisional application No. 63/735,170, filed on Dec. 17, 2024.

(51) Int. Cl. F28D 15/04; F28D 15/06; F28D 15/02

(52) U.S. Cl. CPC F28D 15/043; F28D 15/06; F28D 2015/0225; F28F 2260/02; F28F 2280/00

(57) ABSTRACT

An oscillating heat pipe (OHP) is provided. The OHP includes a heat pipe microchannel formed in a loop with a serpentine pattern. The serpentine pattern includes curved channels extending through cooling and heating sections and elongate channels extending through an adiabatic section defined between the cooling and heating sections. The OHP further includes a wick, a branch connected to a corresponding one of the elongate channels and a heating element. The branch is receptive of fluid from the corresponding one of the elongate channels via the wick. The heating element is disposed to heat the fluid in the branch.

### CROSS-REFERENCE TO RELATED APPLICATIONS

This application claims the benefit of priority to U.S. Application No. 63/735,170 filed December 17, 2024, the disclosure of which is incorporated herein by reference in its entirety.

### BACKGROUND

The present disclosure relates to oscillating heat pipes (OHPs) and pulsating heat pipes (PHPs) and, more particularly, to a dual-phase fluid flow thruster for a heat pipe microchannel of an OHP and/or a PHP.

An OHP (or a PHP, the following description will generally refer only to OHPs for purposes of clarity and brevity though it is to be understood that OHPs and PHPs are interchangeable within the context of the following description) includes a heat pipe microchannel that is partially filled with fluid in a liquid phase. The heat pipe microchannel is formed in a loop with a serpentine pattern that extends between a condensing section and an evaporating section with an adiabatic section between the condensing section and the evaporating section. A typical OHP operates as follows: heat is absorbed by liquid segments in the evaporating section whereby a tail of each liquid segment turns into a vapor segment, each vapor segment is adjacent to a corresponding liquid segment and expands, heat-carrying liquid of the corresponding liquid segment is pushed by the vapor segment to the condensing section and heat is removed from each liquid segment in the condensing section whereby vapor condenses back into a liquid and rejoins an adjacent liquid segment such that the vapor segment shrinks.

The operations listed above can happen simultaneously across several serpentine passes of the OHP channel path and can induce a chaotic oscillatory motion.

### BRIEF DESCRIPTION

According to an aspect of the disclosure, an oscillating heat pipe (OHP) is provided. The OHP includes a heat pipe microchannel formed in a loop with a serpentine pattern. The serpentine pattern includes curved channels extending through cooling and heating sections and elongate channels extending through an adiabatic section defined between the cooling and heating sections. The OHP further includes a wick, a branch connected to a corresponding one of the elongate channels and a heating element. The branch is receptive of fluid from the corresponding one of the elongate channels via the wick. The heating element is disposed to heat the fluid in the branch.

In accordance with one or more additional and/or alternative embodiments, the heating element is operable to induce a vapor jet for communication with the corresponding one of the elongate channels to provide a directional bias and boost to fluid movement therein.

In accordance with one or more additional and/or alternative embodiments, the wick includes porous media, the porous media includes a capillary action substrate and the wick includes a sealant to seal the porous media and the heating element includes at least one or more of a nichrome wire and a functional electrical component that generates waste heat.

In accordance with one or more additional and/or alternative embodiments, the porous media is formed to define a vent hole directed along the branch.

In accordance with one or more additional and/or alternative embodiments, the OHP further includes a controller coupled with the heating element and configured to actively control an operation of the heating element.

In accordance with one or more additional and/or alternative embodiments, the branch has a channel geometry that biases vapor flow to create a pressure differential with respect to the corresponding one of the elongate channels.

In accordance with one or more additional and/or alternative embodiments, the branch includes a heating portion, which is fluidly communicative with the corresponding one of the elongate channels via the wick and a connecting portion, which is fluidly interposed between the heating portion and the corresponding one of the elongate channels. The heating portion is substantially parallel with the corresponding one of the elongate channels and the connecting portion forms an acute angle pointing toward the cooling section with the corresponding one of the elongate channels.

In accordance with one or more additional and/or alternative embodiments, the OHP further includes at least one or more secondary heating elements disposed in at least one of the heating section and the adiabatic section.

In accordance with one or more additional and/or alternative embodiments, the wick, the branch and the heating element are each provided in plural numbers.

According to an aspect of the disclosure, an oscillating heat pipe (OHP) is provided and includes a heat pipe microchannel formed in a loop with a serpentine pattern. The serpentine pattern includes curved channels extending through cooling and heating sections and elongate channels extending through an adiabatic section defined between the cooling and heating sections. The OHP further includes a wick, a branch connected to a corresponding one of the elongate channels a heating element and a controller. The branch is receptive of fluid from the corresponding one of the elongate channels via the wick. The heating element is disposed to heat the fluid in the branch. The heating element is operable to induce a vapor jet for communication with the corresponding one of the elongate channels to provide a directional bias and boost to fluid movement therein. The controller is coupled with the heating element and is configured to actively control an operation of the heating element.

In accordance with one or more additional and/or alternative embodiments, the wick includes porous media, the porous media includes a capillary action substrate and the wick includes a sealant to seal the porous media and the heating element includes at least one or more of a nichrome wire and a functional electrical component that generates waste heat.

In accordance with one or more additional and/or alternative embodiments, the porous media is formed to define a vent hole directed along the branch.

In accordance with one or more additional and/or alternative embodiments, the branch has a channel geometry that biases vapor flow to create a pressure differential with respect to the corresponding one of the elongate channels.

In accordance with one or more additional and/or alternative embodiments, the branch includes a heating portion, which is fluidly communicative with the corresponding one of the elongate channels via the wick and a connecting portion, which is fluidly interposed between the heating portion and the corresponding one of the elongate channels. The heating portion is substantially parallel with the corresponding one of the elongate channels. The connecting portion forms an acute angle pointing toward the cooling section with the corresponding one of the elongate channels.

In accordance with one or more additional and/or alternative embodiments, the OHP further includes at least one or more secondary heating elements disposed in at least one of the heating section and the adiabatic section.

In accordance with one or more additional and/or alternative embodiments, the wick, the branch and the heating element are each provided in plural numbers.

According to an aspect of the disclosure, a method of fabricating an oscillating heat pipe (OHP) is provided and includes forming a heat pipe microchannel in a loop with a serpentine pattern. The serpentine pattern includes curved channels extending through cooling and heating sections and elongate channels extending through an adiabatic section defined between the cooling and heating sections. The method further includes connecting a branch to a corresponding one of the elongate channels, arranging a wick between the branch and the corresponding one of the elongate channels whereby the branch is receptive of fluid from the corresponding one of the elongate channels via the wick and disposing a heating element to heat the fluid in the branch to induce a vapor jet for communication with the corresponding one of the elongate channels to provide a directional bias and boost to fluid movement therein.

In accordance with one or more additional and/or alternative embodiments, the method further includes configuring controller to actively control an operation of the heating element.

In accordance with one or more additional and/or alternative embodiments, the wick includes porous media and the porous media includes a capillary action substrate and the method further includes sealing the porous media.

In accordance with one or more additional and/or alternative embodiments, the connecting of the branch to the corresponding one of the elongate channels includes forming the branch to include a heating portion, which is fluidly communicative with the corresponding one of the elongate channels via the wick, and a connecting portion, which is fluidly interposed between the heating portion and the corresponding one of the elongate channels. The heating portion is substantially parallel with the corresponding one of the elongate channels. The connecting portion forms an acute angle pointing toward the cooling section with the corresponding one of the elongate channels.

Additional features and advantages are realized through the techniques of the present disclosure. Other embodiments and aspects of the disclosure are described in detail herein and are considered a part of the claimed technical concept.

For a better understanding of the disclosure with the advantages and the features, refer to the description and to the drawings.

### BRIEF DESCRIPTION OF THE DRAWINGS

For a more complete understanding of this disclosure, reference is now made to the following brief description, taken in connection with the accompanying drawings and detailed description, wherein like reference numerals represent like parts:

FIG. 1 is a plan view of an OHP with directional biasing and boosting in accordance with embodiments;

FIG. 2 is a perspective view of a portion of the OHP of FIG. 1 in accordance with embodiments;

FIG. 3 is a schematic illustration of a wick of the OHP of FIG. 1 in accordance with embodiments;

FIG. 4 is a perspective view of a portion of the OHP of FIG. 1 with a porous media formed to define a vent hole in accordance with embodiments; and

FIG. 5 is a flow diagram illustrating a method of fabricating an OHP with directional biasing and boosting in accordance with embodiments.

### DETAILED DESCRIPTION

In an OHP, at elevated heat inputs, oscillations caused by the movements of the liquid and vapor through the serpentine passes can cease and become in effect unidirectional flow. This unidirectional flow of working fluid in the OHP could reduce the temperature fluctuation of the evaporator section and enhance the heat transfer performance of the OHP. In an event of unwanted working fluid and/or some combination of pooling or accumulation, this mechanism associated with unidirectional flow can be used to re-distribute working fluid across channels to prime the OHP for faster startup.

In some OHPs, which are relatively long and in which fluid needs to be pushed along extended channels, the fluid may run out of momentum due to adiabatic friction between the fluid and interior walls of the extended channels. In these cases, pressure from heated vapor may not be sufficient to overcome the loss of momentum due to the adiabatic friction.

Thus, as will be described below, an OHP is provided in which a collection of elements are built into the OHP and porous media acts as a partition between a primary fluid transport channel and a small channel branch that is a branch off of the primary fluid transport channel. The porous media collects some of the liquid fluid as it passes by and wicks the liquid fluid through capillary action to the small channel branch. Adjacent to the small channel branch is a heating device, such as at least one or more of a nichrome wire and a functional electrical component that generates waste heat, which applies heat to evaporate the liquid that has transported into the small channel branch. This generates vapor with a pressure differential as compared to the primary fluid transport channel. As such, the vapor that is generated in the small channel branch is thrusted out of the small channel branch and into the primary fluid transport channel at an angle to assist the flow of working fluid through the primary fluid transport channel.

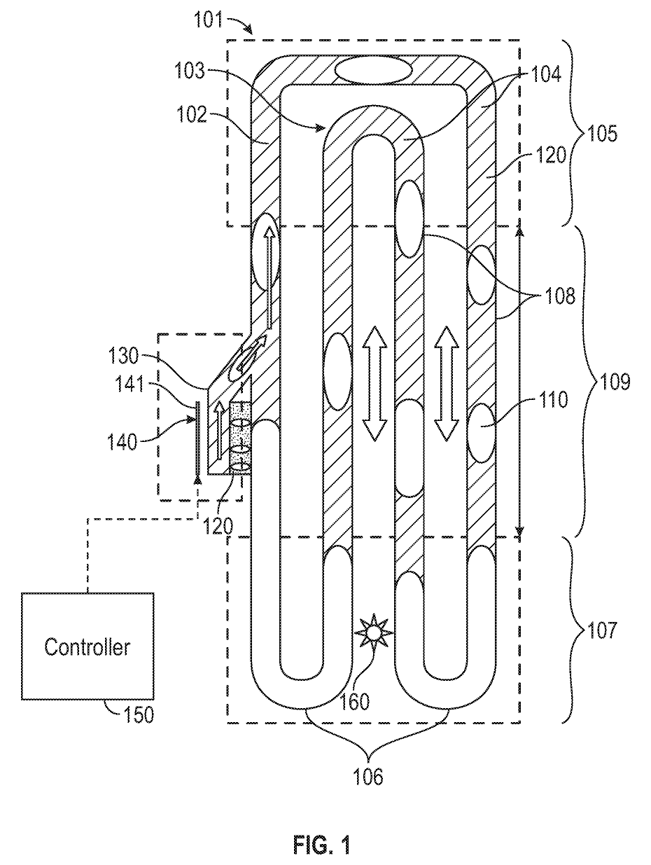

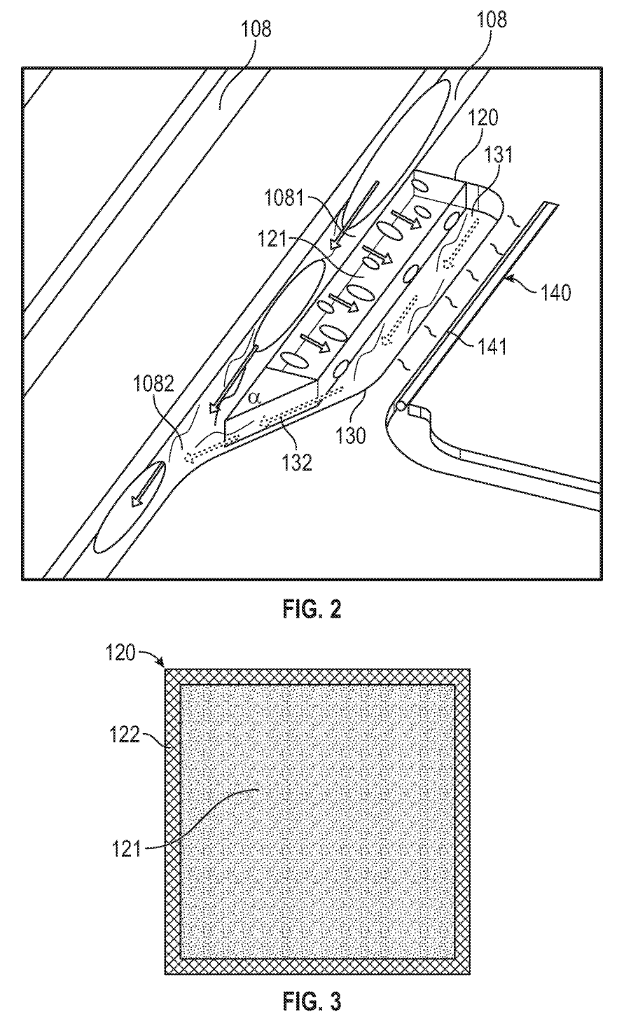

With reference to FIGS. 1 and 2, an OHP 101 is provided and includes a heat pipe microchannel 102 that is formed in a loop with a serpentine pattern 103. The serpentine pattern 103 includes first curved channels 104 extending through a condensing/cooling section 105 (hereinafter referred to as “a cooling section 105”), second curved channels 106 extending through an evaporating/heating section 107 (hereinafter referred to as a “heating section 107”) and elongate channels 108. The elongate channels 108 extend between the first curved channels 104 and the second curved channels 106 and through an adiabatic section 109 that is defined between the cooling section 105 and the heating section 107.

During an operation of the OHP 101, fluid in the second curved channels 106 of the heat pipe microchannel 102 is heated in the heating section 107 and forms vapor plugs 110 that are interleaved with liquid slugs 120. The vapor plugs 110 encourage flow of the liquid slugs 120 out of the heating section 107, along the elongate channels 108 through the adiabatic section 109 and to the first curved channels 104 in the cooling section 105. Within the first curved channels 104 in the cooling section 105, the vapor plugs 110 become reduced in size as the vapor condenses back into liquid.

Where the OHP 101 and the elongate channels 108 are relatively long, adiabatic friction between the fluid and interior walls of the elongate channels 108 tends to reduce a momentum of the fluid flow. In conventional OHPs, this adiabatic friction phenomenon can reduce an effective heat transfer capability of the conventional OHPs. For the OHP 101 described herein, the fluid flow is provided with a directional bias and a boost within at least one of the elongate channels 108 as described below.

As shown in FIG. 1, the OHP 101 further includes a wick 120, a branch 130 and a heating element 140. The branch 130 is connected to a corresponding one of the elongate channels 108 and is receptive of fluid in liquid phase from the corresponding one of the elongate channels 108 via capillary action through the wick 120. The heating element 140 is disposed to heat the fluid in the branch 130 and can include or be provided as at least one or more of a nichrome wire 141 and a functional electrical component that generates waste heat. In greater detail, the heating element 140 is operable to induce a vapor jet for communication with the corresponding one of the elongate channels 108 to provide the directional bias and the boost to fluid movement in the corresponding one of the elongate channels 108. The OHP 101 can further include a controller 150, which is coupled with the heating element 140 and which is configured to actively control an operation of the heating element 140, as well as temperature and pressure sensors that are deployed throughout the OHP 101 to sense a condition of fluid flow. The controller 150 can be receptive of readings of the temperature and pressure sensors and can be configured to determine, based on those readings, when to activate the heating element 140 and how much heating is required to maintain fluid flow.

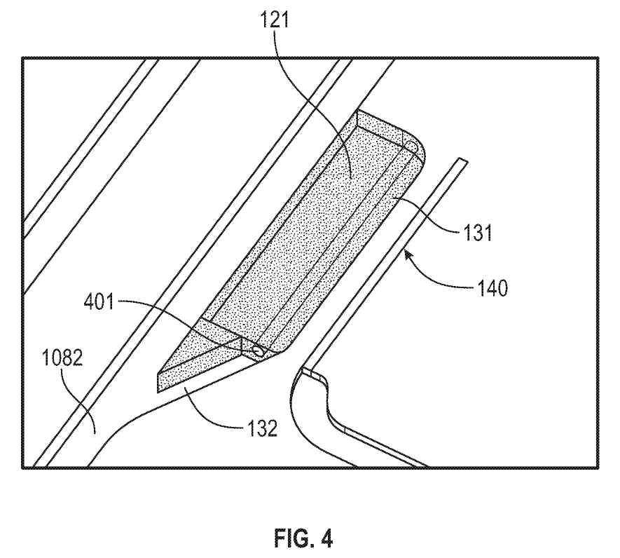

With continued reference to FIGS. 1 and 2 and with additional reference to FIG. 3, the wick 120 can include a porous media 121 (see FIGS. 2 and 3), such as a capillary action substrate like foam or another suitable material that is able to provide capillary action for liquid transport. In these or other cases, the wick 120 can further include a sealant 122 to seal the porous media 121. As shown in FIG. 3, the sealant 122 can be provided as a metallic or polymeric material that surrounds an exterior of the porous media 121 to effectively define a passage from the corresponding one of the elongate channels 108 to the branch 130 from which fluid that is moving through the porous media 121 by the capillary action cannot escape.

As shown in FIGS. 1 and 2, the branch 130 has a channel geometry that biases vapor flow to create a pressure differential with respect to the corresponding one of the elongate channels 108. That is, in accordance with embodiments, the branch 130 can include an upstream heating portion 131, which is fluidly communicative with an upstream section 1081 of the corresponding one of the elongate channels 108 via the capillary action through the wick 120, and a downstream connecting portion 132. The downstream connecting portion 132 is fluidly interposed between the upstream heating portion 131 and a downstream section 1082 of the corresponding one of the elongate channels 108. The upstream heating portion 131 can be substantially parallel with the upstream section 1081 of the corresponding one of the elongate channels 108 and the downstream connecting portion 132 can form a sharp and acute angle α (i.e., about 30 degrees) that points toward the cooling section 105 with the downstream section 1082 of the corresponding one of the elongate channels 108.

In accordance with one or more additional and/or alternative embodiments, the OHP 101 can further include at least one or more secondary heating elements 160 that can be disposed in or proximate to at least one of the heating section 107 and the adiabatic section 109 to increase and/or maintain the heating of the fluid and the formation of the vapor plugs 110. In addition, although not shown in FIGS. 1 and 2, it is to be understood that the wick 120, the branch 130 and the heating element 140 can each be provided in plural numbers thereof to increase the directional bias and the boost applied to the fluid.

With reference to FIG. 4 and in accordance with further embodiments, the porous media 121 can be formed to define a tunnel and a vent hole 401. In these or other cases, the porous media 121 can be brought relatively close to the heating element 140 by occupying an entirety of the space within the upstream heating portion 131. The tunnel and the vent hole 401 can extend along the upstream heat portion 131 and can be directed along the downstream connecting portion 132 to allow for vapor to escape from the porous media 121 and to encourage the vapor to travel toward the downstream section 1082.

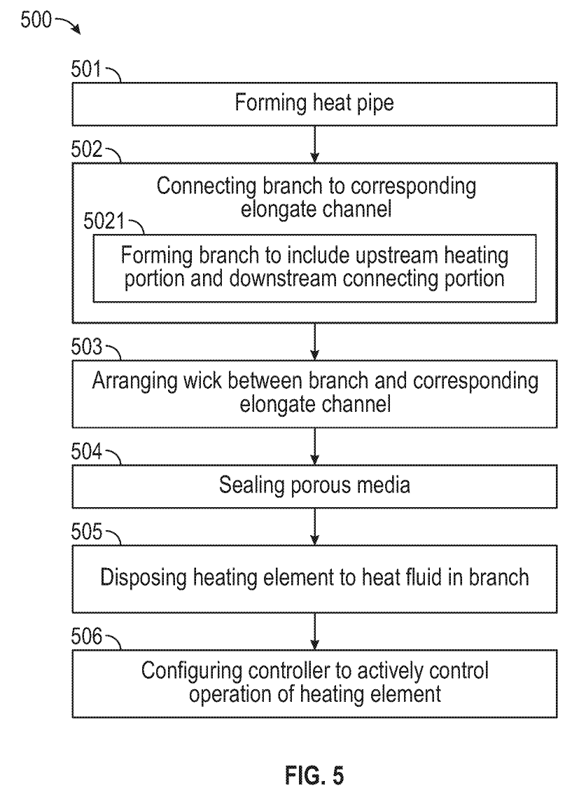

With reference to FIG. 5, a method 500 of fabricating an OHP, such as the OHP 101 of FIGS. 1-4, is provided. As shown in FIG. 5, the method 500 can be executed by vacuum brazing, additive manufacturing and/or other similar processes and includes forming a heat pipe microchannel in a loop with a serpentine pattern as described above (block 501), connecting a branch to a corresponding one of the elongate channels (block 502), arranging a wick between the branch and the corresponding one of the elongate channels whereby the branch is receptive of fluid from the corresponding one of the elongate channels via the wick (block 503) and, in some cases, sealing porous media of the wick (block 504). In addition, the method 500 includes disposing a heating element to heat the fluid in the branch to induce a vapor jet for communication with the corresponding one of the elongate channels to provide a directional bias and boost to fluid movement therein (block 505) and, in some cases, configuring controller to actively control an operation of the heating element (block 506).

The connecting of the branch to the corresponding one of the elongate channels of block 502 can include forming the branch to include an upstream heating portion, which is fluidly communicative with an upstream section of the corresponding one of the elongate channels via the wick, and a downstream connecting portion, which is fluidly interposed between the upstream heating portion and a downstream section of the corresponding one of the elongate channels (block 5021) where the upstream heating portion is substantially parallel with the upstream section of the corresponding one of the elongate channels and the downstream connecting portion forms a shard and acute angle α pointing toward the cooling section of the OHP with the downstream section of the corresponding one of the elongate channels.

Technical effects and benefits of the present disclosure are the provision of an OHP in which a branch and a heating element provide for a directional bias and a boost for fluid flow in primary fluid transport channels to thereby reduce a loss of fluid momentum in the primary fluid transport channels and to thus increase a heat transfer capability of the OHP. This is particularly useful in a relatively long OHP with relatively long primary fluid transport channels that is provided for removing heat from associated electronics. This can allow for a priming of an OHP to get up to peak operation efficiency quicker along with some transient effects. This can also allow in some cases for the removal of certain pumping systems, which can be costly and prone to failure.

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the technical concepts in the form disclosed. Many modifications and variations will be apparent to those of ordinary skill in the art without departing from the scope and spirit of the disclosure. The embodiments were chosen and described in order to best explain the principles of the disclosure and the practical application, and to enable others of ordinary skill in the art to understand the disclosure for various embodiments with various modifications as are suited to the particular use contemplated.

While the preferred embodiments to the disclosure have been described, it will be understood that those skilled in the art, both now and in the future, may make various improvements and enhancements which fall within the scope of the claims which follow. These claims should be construed to maintain the proper protection for the disclosure first described.

What is claimed is:

1. An oscillating heat pipe (OHP), comprising:
a heat pipe microchannel formed in a loop with a serpentine pattern comprising:
curved channels extending through cooling and heating sections; and
elongate channels extending through an adiabatic section defined between the cooling and heating sections;
a wick;
a branch connected to a corresponding one of the elongate channels, the branch being receptive of fluid from the corresponding one of the elongate channels via the wick; and
a heating element disposed to heat the fluid in the branch.

2. The OHP according to claim 1, wherein the heating element is operable to induce a vapor jet for communication with the corresponding one of the elongate channels to provide a directional bias and boost to fluid movement therein.

3. The OHP according to claim 1, wherein:
the wick comprises porous media, the porous media comprises a capillary action substrate and the wick comprises a sealant to seal the porous media, and
the heating element comprises at least one or more of a nichrome wire and a functional electrical component that generates waste heat.

4. The OHP according to claim 3, wherein the porous media is formed to define a vent hole directed along the branch.

5. The OHP according to claim 1, further comprising a controller coupled with the heating element and configured to actively control an operation of the heating element.

6. The OHP according to claim 1, wherein the branch has a channel geometry that biases vapor flow to create a pressure differential with respect to the corresponding one of the elongate channels.

7. The OHP according to claim 1, wherein the branch comprises:
a heating portion, which is fluidly communicative with the corresponding one of the elongate channels via the wick; and
a connecting portion, which is fluidly interposed between the heating portion and the corresponding one of the elongate channels,
the heating portion being substantially parallel with the corresponding one of the elongate channels, and
the connecting portion forming an acute angle pointing toward the cooling section with the corresponding one of the elongate channels.

8. The OHP according to claim 1, further comprising at least one or more secondary heating elements disposed in at least one of the heating section and the adiabatic section.

9. The OHP according to claim 1, wherein the wick, the branch and the heating element are each provided in plural numbers.

10. An oscillating heat pipe (OHP), comprising:
a heat pipe microchannel formed in a loop with a serpentine pattern comprising:
curved channels extending through cooling and heating sections; and
elongate channels extending through an adiabatic section defined between the cooling and heating sections;
a wick;
a branch connected to a corresponding one of the elongate channels, the branch being receptive of fluid from the corresponding one of the elongate channels via the wick;
a heating element disposed to heat the fluid in the branch, the heating element being operable to induce a vapor jet for communication with the corresponding one of the elongate channels to provide a directional bias and boost to fluid movement therein; and
a controller coupled with the heating element and configured to actively control an operation of the heating element.

11. The OHP according to claim 10, wherein:
the wick comprises porous media, the porous media comprises a capillary action substrate and the wick comprises a sealant to seal the porous media, and
the heating element comprises at least one or more of a nichrome wire and a functional electrical component that generates waste heat.

12. The OHP according to claim 11, wherein the porous media is formed to define a vent hole directed along the branch.

13. The OHP according to claim 10, wherein the branch has a channel geometry that biases vapor flow to create a pressure differential with respect to the corresponding one of the elongate channels.

14. The OHP according to claim 10, wherein the branch comprises:
a heating portion, which is fluidly communicative with the corresponding one of the elongate channels via the wick; and
a connecting portion, which is fluidly interposed between the heating portion and the corresponding one of the elongate channels,
the heating portion being substantially parallel with the corresponding one of the elongate channels, and
the connecting portion forming an acute angle pointing toward the cooling section with the corresponding one of the elongate channels.

15. The OHP according to claim 10, further comprising at least one or more secondary heating elements disposed in at least one of the heating section and the adiabatic section.

16. The OHP according to claim 10, wherein the wick, the branch and the heating element are each provided in plural numbers.

17. A method of fabricating an oscillating heat pipe (OHP), the method comprising:
forming a heat pipe microchannel in a loop with a serpentine pattern comprising:
curved channels extending through cooling and heating sections; and
elongate channels extending through an adiabatic section defined between the cooling and heating sections;
connecting a branch to a corresponding one of the elongate channels;
arranging a wick between the branch and the corresponding one of the elongate channels whereby the branch is receptive of fluid from the corresponding one of the elongate channels via the wick; and
disposing a heating element to heat the fluid in the branch to induce a vapor jet for communication with the corresponding one of the elongate channels to provide a directional bias and boost to fluid movement therein.

18. The method according to claim 17, further comprising configuring controller to actively control an operation of the heating element.

19. The method according to claim 17, wherein the wick comprises porous media and the porous media comprises a capillary action substrate and the method further comprises sealing the porous media.

20. The method according to claim 17, wherein the connecting of the branch to the corresponding one of the elongate channels comprises forming the branch to comprise:
a heating portion, which is fluidly communicative with the corresponding one of the elongate channels via the wick; and
a connecting portion, which is fluidly interposed between the heating portion and the corresponding one of the elongate channels,
the heating portion being substantially parallel with the corresponding one of the elongate channels, and
the connecting portion forming an acute angle pointing toward the cooling section with the corresponding one of the elongate channels.
